(19) United States
(12) Patent Application Publication
(10) Pub. No.: US 2006/0017016 A1
(43) Pub. Date: Jan. 26, 2006

(54) Method for the removal of a microscopic sample from a substrate

(75) Inventor: Hendrik Gezinus Tappel, Eindhoven (NL)

Correspondence Address: MICHAEL O. SCHEINBERG, P.O. BOX 164140, AUSTIN, TX, 78716-4140, US

(73) Assignee: FEI Company, Hillsboro, OR (US)

(21) Appl. No.: 11/167,617

(22) Filed: Jun. 27, 2005

(30) Foreign Application Priority Data
Jul. 1, 2004 (NL) 04076892.1

(51) Int. Cl. H01J 37/08

(52) U.S. Cl. 250/492.21

(57) ABSTRACT

The invention provides a method for the removal of a microscopic sample 1 from a substrate 2, comprising:
performing a cutting process whereby the substrate 2 is irradiated with a beam 4 such that the sample 1 is cut out of the substrate 2, and
performing an adhesion process whereby the sample 1 is adhered to a probe 3, characterized in that
the cutting process, during at least part of the duration of the cutting process, is carried out by at least two beams 4, 5 simultaneously.
   By performing cutting with at least two beams, the sample 1 can be extracted without having to change the orientation of the substrate 2 with respect to the means that produce the beams. Both the act of working with two beams simultaneously and the attendant possibility of keeping the orientation constant provide time-savings compared to a method whereby cutting is only performed with a single beam.

The invention pertains to a method for the removal of a microscopic sample from a substrate, comprising the steps of:
performing a cutting process whereby the substrate is irradiated with a beam such that the sample is cut out of the substrate, and
performing an adhesion process whereby the sample is adhered to a probe.

The invention additionally pertains to a particle-optical device embodied for the performance of the method.

Such a method is known from U.S. Pat. document No. 5,270,552.

A method such as this is employed in particular in the semiconductor industry, where samples of microscopic proportions are taken out of substrates such as wafers in order to facilitate analysis and/or further processing. These days, such samples have dimensions of the order of magnitude of 10 μm at a thickness of 100 nm. A trend exists towards an even further size-reduction in the structures of interest, and, as a result hereof, a further size-reduction in the samples to be extracted.

The analyses which are made of such microscopic samples can be carried out, for example, with the aid of a TEM (Transmission Electron Microscope), SEM (Scanning Electron Microscope), SIMS (Secondary Ion Mass Spectroscope) or with X-Ray analysis equipment. The further processing/manipulations can consist of, for example, making the sample thinner with the aid of an ion beam for the purposes of analysis with the aid of a TEM.

With the method described in the aforementioned patent document, a needle-shaped probe is moved by a manipulator to a position on a substrate where a sample is to be extracted. The sample is cut away from the substrate by removing material from two different directions with a focused ion-beam.

Prior to completely cutting the sample out of the substrate, the sample is adhered to the extremity of the probe by means of, for example, metal deposition. After the sample is completely cut away the sample adhered to the probe is moved to another position with the aid of the manipulator.

It is to be noted that, prior to commencing the adhesion process, part of the cutting process must first be performed. After all, the presence of the needle-shaped probe causes shadow-formation; the presence of the probe will render a portion of the substrate invisible to the ion-beam deployed. For that reason, it is necessary to first commence the cutting process and then only move the probe to the sample position upon completion of the cutting in that region of the substrate that will come to lie in the shadow of the sample holder. Only thereafter can the adhesion process be started, whereupon the cutting process can be recommenced in order to completely extract the sample.

It is an aim of the invention to provide a method of the type mentioned in the opening paragraph which provides for time-saving compared to the known method.

To that end, the method according to the invention is characterized in that the cutting process, during at least part of the duration of the cutting process, is carried out by two beams simultaneously.

In the known method, the sample is cut from the substrate by irradiating the substrate sequentially from two different directions. By carrying out the method with the aid of a device wherein multiple cutting beams are active at the same time, the irradiation can occur from different directions simultaneously with two or more beams. This leads to the intended time-saving.

In an embodiment of the method according to the invention the orientation of the substrate with respect to the radiation sources remains unchanged during the cutting process.

In order to cut the sample away from the substrate, a wedge-shaped cut will generally have to be made. In the known method a first cut is first made, whereupon the angle of incidence of the cutting beam with respect to the substrate is changed and a second cut is made. Altering the angle of incidence of the cutting beam usually occurs through changing the orientation of the substrate.

It is to be noted that a change in the orientation of the substrate with respect to the beam will usually imply an attendant change in the position of the substrate. Because of this, changing the orientation will require a repositioning of the substrate with respect to the means which produce the beams.

If, however, more than one beam is available, these beams will generally subtend an angle with respect to one another. Because of this, the sample can be completely extracted without having to change the orientation of the substrate.

The elimination of the need to reposition saves a non-negligible amount of time. After all, the repositioning of substrate and beam must occur with a high degree of accuracy. These days, a sample to be extracted will have dimensions of the order of magnitude of 10 μm at a thickness of 100 nm. Repositioning will therefore generally comprise not only moving the substrate, but also determining with sub-micron accuracy the position of the sample with respect to the means which produce both of the beams.

It is to be noted that in, in general, the beam is positioned with respect to the substrate with the aid of deflecting means. The orientation of the beam varies hereby slightly with respect to the substrate. However, this change of angle cannot generally be used to cut out the sample all around. After all, in order to cut away a wedge-shaped sample, it is a requirement that the beams intersect each other in the sample, a feat which is not easily achieved when the beams are deflected by deflection means that are placed outside the substrate.

In another embodiment of the method according to the invention, the adhesion process comprises irradiating with a beam.

Adhering the sample to the probe with the aid of a beam can take place using a method known per se, whereby a metal deposition is applied, with the aid of, for example, an ion beam. This adhesion can be carried out using one of the beams with which, for at least part of the time, the cutting process is performed, but the beam can also be a different beam than the beams which perform the cutting.

It is to be noted that it is possible to change the function of an ion-beam from erosion (the removal of material) to deposition (the application of material) by changing certain properties of the beam, such as the current-density.

It is also to be noted that the beam with which the adhesion process is performed does not necessarily have to be of the same type as the type with which the cutting process is performed. It is conceivable that a beam of ions be used for cutting and a beam of photons or an electron beam be used for the adhesion process.

In a further method according to the invention, the adhesion process and the cutting process overlap each other temporally.

Before rounding off the cutting process it is desired that the sample be affixed to the probe. By allowing the cutting process and the adhesion process to overlap each other in time, a further time-saving is realized. One can envisage hereby that cutting is at first performed with two beams, after which one of the beams performs cutting while the other beam simultaneously performs adhesion.

In a preferential embodiment of the method according to the invention, the aforementioned irradiation comprises irradiating with beams of electrically charged particles.

The use of a beam of electrically-charged particles, in particular a beam of ions, for the cutting process is a method known per se. Also, for the adhesion process, the application of a metal deposit with the aid of an ion beam is a method known per se.

It is also to be noted that the irradiation with electrically charged particles can occur coincident with, for example, the presence of special gases, whereby, for example, the cutting-speed of the beam(s) can be increased or the application of a metal deposition becomes possible.

The invention will be further elucidated on the basis of figures, whereby corresponding elements are depicted using the same reference numbers. To this end:

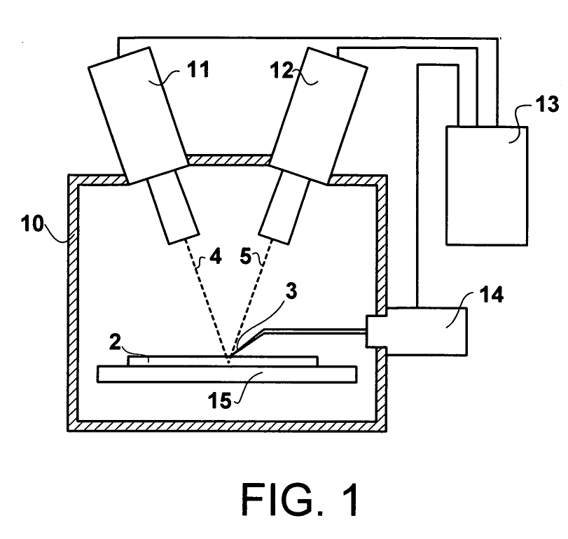

FIG. 1 shows a schematic depiction of a particle-optical device according to the invention, equipped with two columns, each of which produces an ion beam,

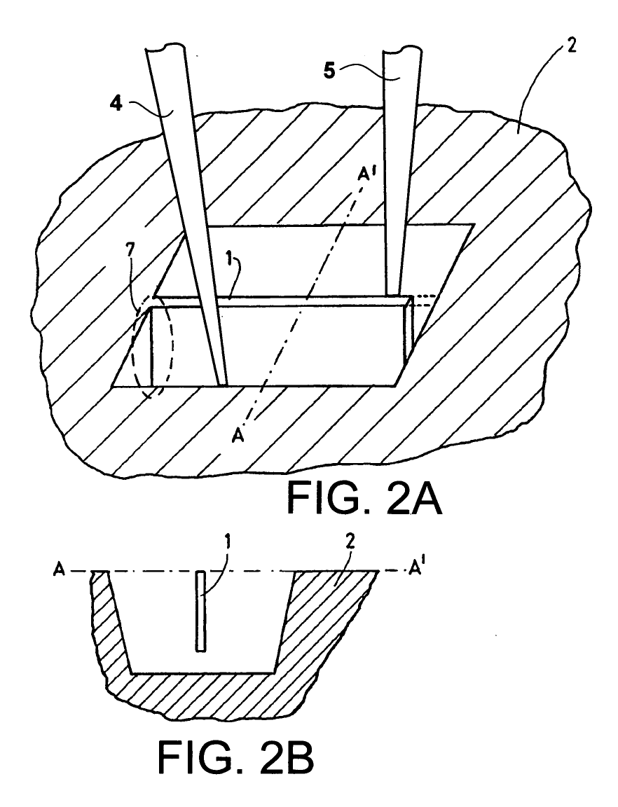

FIG. 2A shows a schematic representation of a substrate from which a sample is cut away by two beams,

FIG. 2B shows a schematic representation of a transverse cross-section from FIG. 2A, and

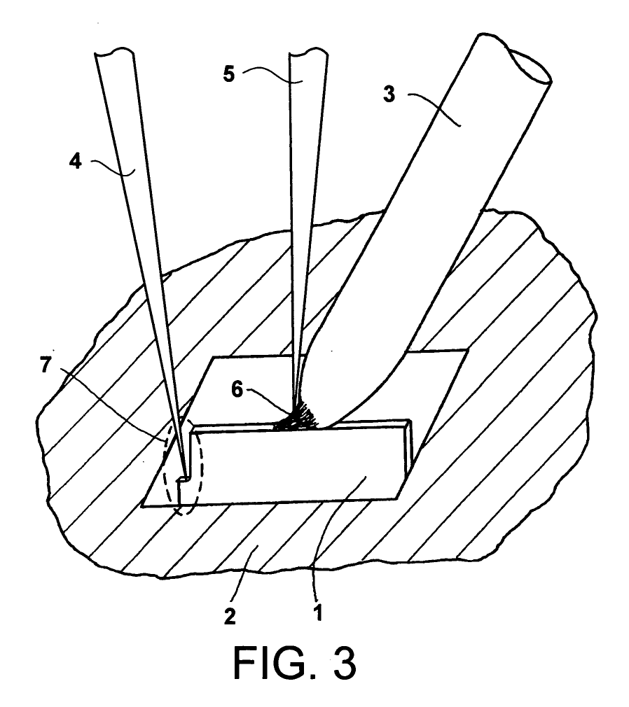

FIG. 3 shows a schematic representation of a substrate with a partially cut-away sample that is being affixed to a needle-shaped extremity of a probe.

FIG. 1 schematically depicts a particle-optical device suited to the performance of the method according to the invention, equipped with two columns 11 and 12, each of which produces an ion beam 4 and 5, respectively.

The particle-optical device comprises a vacuum chamber 10, a first column 11—mounted on the vacuum chamber 10—for the production of a first ion beam 4, a second column 12—mounted on the vacuum chamber 10—for the production of a second ion beam 5, control means 13 embodied to simultaneously operate columns 11 and 12, a probe 14 which can be manipulated, and a substrate carrier 15 which can be positioned.

The vacuum chamber 10 is maintained, by means of (non-depicted) evacuation means, in vacuum or at least at a pressure significantly less than atmospheric pressure. The columns 11 and 12 are mounted to the vacuum chamber 10 at such an orientation that the ion beams 4 and 5 produced by these columns practically intersect each other.

A substrate in the form of a wafer 2 placed on the positionable substrate carrier 15 is positioned with the aid of the positionable substrate carrier 15 in such a manner that a sample 1 which is to be extracted lies practically at the intersection of the two beams 4 and 5. The cutting process can commence hereafter.

FIGS. 2A and 2B schematically depict a substrate in the form of a wafer 2 from which a sample 1 is cut away by two beams 4 and 5.

FIG. 2A shows how sample 1 is cut away from wafer 2 by two ion beams 4 and 5 simultaneously. Because the two beams 4 and 5 subtend an angle with respect to each other, it is possible to cut out the sample 1 all around without the wafer 2 having to assume another orientation with respect to the columns 11 and 12 that produce the beams 4 and 5.

In the situation shown, the bottom side of sample 1 is already largely cut away, whereupon the sample 1 will only remain connected to the wafer 2 by the connection 7 between the wafer 2 and the sample 1.

These days, a sample to be extracted will typically have dimensions of the order of magnitude of 10 μm (that is to say length perpendicular to line AA′) and a thickness (that is to say dimension in the direction of line AA′) of 100 nm.

FIG. 2B shows a transverse cross-section according to line AA′ depicted in FIG. 2A, whereby it can be clearly seen that the sample 1 is free at the lower surface from the wafer 2.

FIG. 3 schematically depicts a sample 1 that is being affixed at the extremity of the probe 3.

The cutting process in the depicted situation is sufficiently progressed that no further shadow-effect of the probe 14 is to be feared. The needle-shaped extremity 3 of the probe 14, which can be manipulated, is moved to the position of the sample 1 to be extracted. The sample 1 is connected to the extremity 3 of probe 14 by irradiation with an ion beam 5, whereby a metal deposit 6 adheres the sample 1 to the probe 14. At the same time, the remaining connection 7 between the sample 1 and the wafer 2 is removed with ion beam 4. After the cutting is completely finished, the sample 1 that is adhered to the probe 14 can be taken away.

1. A method for the removal of a microscopic sample from a substrate, comprising:
performing a cutting process whereby the substrate is irradiated with a beam such that the sample is cut out of the substrates, and
performing an adhesion process whereby the sample is adhered to a probe, characterized in that
the cutting process, during at least part of the duration of the cutting process, is carried out by at least two beams simultaneously.

2. A method according to claim 1 whereby, during the cutting process, the orientation of the substrate in relation to the means which produce the two beams remains unchanged.

3. A method according to claim 1, whereby the adhesion process comprises the irradiation of the sample with a beam.

4. A method according to claim 3, whereby the adhesion process and the cutting process overlap each other temporally.

5. A method according to claim 1, whereby the irradiation comprises irradiating with beams of electrically charged particles.

6. A particle-optical device embodied to extract samples from a substrate, comprising:
a particle-optical column for the production, focusing and positioning of a first ion beam,
controller for the control of the production, focusing and positioning of the ion beam, and
a probe which can be manipulated,
characterized in that
the device is provided with a second particle-optical column for the production, focusing and positioning of a second ion beam, and
the control means are embodied in such a manner that both ion columns can simultaneously produce an ion beam.

7. A method according to claim 2, whereby the adhesion process comprises the irradiation of the sample with a beam.

8. A method according to claim 7, whereby the adhesion process and the cutting process overlap each other temporally.

9. A method according to claim 2, whereby the irradiation comprises irradiating with beams of electrically charged particles.

10. A method according to claim 3, whereby the irradiation comprises irradiating with beams of electrically charged particles.

11. A method according to claim 4, whereby the irradiation comprises irradiating with beams of electrically charged particles.

12. A method according to claim 7, whereby the irradiation comprises irradiating with beams of electrically charged particles.

13. A method according to claim 8, whereby the irradiation comprises irradiating with beams of electrically charged particles.
